(19) United States
(12) Patent Application Publication
(10) Pub. No.: US 2011/0284914 A1
(43) Pub. Date: Nov. 24, 2011

(54) METHOD FOR MANUFACTURING SUBSTRATE FOR LIGHT EMITTING ELEMENT PACKAGE, AND LIGHT EMITTING ELEMENT PACKAGE

(75) Inventors: Motohiro Suzuki, Tokyo (JP); Naomi Yonemura, Tokyo (JP); Yoshihiko Okajima, Tokyo (JP); Tetsuro Maeda, Tokyo (JP); Eiji Yoshimura, Nagano (JP)

(73) Assignee: DENKI KAGAKU KOGYO KABUSHIKI KAISHA, Tokyo (JP)

(21) Appl. No.: 13/131,257

(22) PCT Filed: Nov. 25, 2008
(86) PCT No.: PCT/JP2008/071341

§ 371 Date: Aug. 15, 2011

(51) Int. Cl. H01L 33/64; B32B 37/02; H05K 1/11

(52) U.S. Cl. 257/99; 174/252; 156/327; 156/324; 257/E33.075

(57) ABSTRACT

A substrate for a light emitting element package provided with a thick metal section formed under a mounting position of a light emitting element, comprising:an insulating layer which is composed of a resin containing heat conductive fillers under the mounting position of said light emitting element and has a heat conductivity of 1.0 W/mK or more; and a metal layer disposed inside said insulating layer and having the thick metal section, wherein a heat conductive mask section is disposed at the top of said thick metal section.

### TECHNICAL FIELD

The present invention relates to a method for manufacturing a substrate for a light emitting element package used in packaging a light emitting element such as a LED chip, as well as to a light emitting element package using a substrate for a light emitting element package manufactured by this manufacturing method.

### BACKGROUND ART

In recent years, as illuminating and light-emitting means that can reduce the weight and thickness and can save electric power consumption, a light emitting diode has been attracting people's attention. As a mode of mounting a light emitting diode, there are known a method of mounting a bare chip (LED chip) of a light emitting diode directly on a circuit board and a method of packaging a LED chip by bonding on a small substrate so that the LED chip can be easily mounted on the circuit board and mounting this LED package on the circuit board.

A conventional LED package has a structure such that a LED chip is die-bonded onto a small substrate; the electrode part of the LED chip and the electrode part of the lead are connected with each other by wire bond or the like, and the resultant is sealed with a sealing resin having a light transmitting property.

On the other hand, a LED chip has a property such that, in an ordinary temperature region for use as an illumination appliance, the light-emitting efficiency increases according as the temperature goes down, and the light-emitting efficiency decreases according as the temperature goes up. For this reason, in a light source apparatus using a light emitting diode, quick dissipation of the heat generated in the LED chip to the outside so as to lower the temperature of the LED chip is an extremely important goal to be achieved in improving the light emitting efficiency of the LED chip. Also, by enhancing the heat dissipation characteristics, the LED chip can be energized with a large electric current, whereby the optical output of the LED chip can be increased.

Therefore, in order to improve the heat dissipation characteristics of a LED chip in place of a conventional light emitting diode, some light source apparatus are proposed in which the LED chip is directly die-bonded to a thermally conductive substrate. For example, in the following patent document 1, there is known an apparatus in which a recess is formed by performing a pressing treatment on a substrate made of a thin aluminum plate and, after a thin insulator film is formed on the surface thereof, a LED chip is die-bonded onto a bottom surface of the recess via the thin insulator film; the wiring pattern formed on the insulator film layer and the electrode on the LED chip surface are electrically connected via a bonding wire; and the inside of the recess is filled with a sealing resin having a light-transmitting property. However, with this substrate, the structure will be complex, raising problems such as a high processing cost.

Also, the following patent document 2 discloses an apparatus in which a substrate for mounting a light emitting element includes a metal substrate, a columnar metal body (metal protrusion) formed by etching at a mounting position of the metal substrate for mounting the light emitting element, an insulating layer formed around the columnar metal body, and an electrode section formed in a neighborhood of said columnar metal body.

Patent Document 1: Japanese Patent Application Laid-open No. 2002-94122 Gazette

Patent Document 2: Japanese Patent Application Laid-open No. 2005-167086 Gazette

### DISCLOSURE OF THE INVENTION

### Problems to be Solved by the Invention

However, according to the studies made by the present inventors, it has been found out that, in the case of mounting a LED chip on the circuit board, it will be important to dispose a columnar metal body at the mounting position thereof; however, in the case of mounting a LED package, there is not necessarily a need to dispose a columnar metal body on its substrate. In other words, it has been found out that, in the case of mounting a LED package, a sufficient heat dissipation property can be obtained by using a resin containing highly heat-conductive inorganic fillers as a material of the insulating layer of the substrate on which the LED package is to be mounted.

When reference is made to the patent document 2 from this viewpoint, with regard to the substrate for mounting a light emitting element disclosed in this document, there has further been a room for improvement as to the penetration structure of the columnar metal body, the wiring for electric power feeding, the insulating layer, and the like in packaging the LED chip. Also, as a method of forming a columnar metal body, reconsideration of the number of manufacturing steps has been desired in view of the production cost reduction.

Also, as a small substrate for packaging a LED chip, there is known one in which the insulating layer is made of ceramics; however, in manufacturing the same, firing of the ceramics and the like will be needed, so that it has not been possible to say that it is advantageous in terms of production costs and the like, and it has been disadvantageous for mass production.

Therefore, an object of the present invention is to provide a substrate for a light emitting element package that can obtain a sufficient heat dissipation effect from a light emitting element and can also enable mass production, cost reduction, and downsizing as a substrate for packaging the light emitting element, a method for manufacturing the same, and a light emitting element package using the substrate for a light emitting element package according to these.

### Means for Solving the Problems

The aforementioned object can be achieved by the present invention such as described below.

A substrate for a light emitting element package according to the present invention is a substrate for a light emitting element package provided with a thick metal section formed under a mounting position of a light emitting element, including:

an insulating layer which is composed of a resin containing heat conductive fillers under the mounting position of said light emitting element and has a heat conductivity of 1.0 W/mK or more; and

a metal layer disposed inside said insulating layer and having the thick metal section,

characterized in that a heat conductive mask section is disposed at the top of said thick metal section.

With this construction, the thick metal section is disposed to stand upright in the inside of the insulating layer having a good heat conductivity, and furthermore, the heat conductive mask section is (disposed by being) top-coated at the top of the thick metal section. Therefore, when a light emitting element is mounted on a mounting surface on one surface side of the insulating layer, for example, the heat generated in the light emitting element is efficiently conducted by the insulating layer having a high heat conductivity, the heat conductive mask section, and the thick metal section. Also, when a light emitting element is mounted on the metal layer surface side opposite to the thick metal section, the heat generated in the light emitting element is efficiently conducted by the heat conductive mask section and the thick metal section, and the heat is efficiently conducted further by the insulating layer having a high heat conductivity. In this manner, a sufficient heat dissipation effect can be obtained as a substrate for packaging.

For the heat conductive mask section, an etching resist in the step of forming the thick metal section, for example, is preferably used as it is. The resist removing step can be omitted, thereby providing a large improvement effect in view of the working efficiency, the production costs, and the like.

Also, a method for manufacturing a light emitting element package according to another aspect of the present invention is a method for manufacturing a substrate for a light emitting element package provided with a thick metal section formed under a mounting position of a light emitting element, characterized by having a lamination step of laminating and integrating a laminate having an insulating adhesive agent which is composed of a resin containing heat conductive fillers and has a heat conductivity of 1.0 W/mK or more and a metal layer member, with a metal layer member having a thick metal section provided with a heat conductive mask section.

With this construction, a laminate having an insulating adhesive agent having a good heat conductivity and a metal layer member can be laminated and integrated with a metal layer member having a thick metal section provided with a heat conductive mask section. By producing the laminate in advance, the production of the substrate for a light emitting element package can be easily carried out, thereby providing an excellent mass production property and enabling cost reduction and downsizing of the package. Further, when a light emitting element is mounted on a mounting surface on one surface side of the insulating layer, for example, the heat generated in the light emitting element is efficiently conducted by the insulating layer having a high heat conductivity, the heat conductive mask section, and the thick metal section. Also, when a light emitting element is mounted on the metal layer surface side opposite to the thick metal section, the heat generated in the light emitting element is efficiently conducted by the heat conductive mask section and the thick metal section, and the heat is efficiently conducted further by the insulating layer having a high heat conductivity. In this manner, a sufficient heat dissipation effect can be obtained as a substrate for packaging.

Also, as one example of a suitable embodiment of the present invention, the laminate having the insulating adhesive agent and the metal layer member and/or the metal layer member having the thick metal section provided with the heat conductive mask section are preferably provided in a roll form in advance. With this construction, the continuous production property and the mass production property will be excellent and also the yield efficiency will be good as compared with the production in sheet units.

Also, a light emitting element package according to another aspect of the present invention is constructed by using a substrate for a light emitting element package described above or a substrate for a light emitting element package manufactured by a manufacturing method described above. Therefore, the light emitting element package can be manufactured at a low cost and in a small scale.

### BRIEF DESCRIPTION OF THE DRAWINGS

FIG. 1 is a cross-sectional view showing one example of a substrate for a light emitting element package of the present invention.

FIG. 2 is a cross-sectional view showing another example of a substrate for a light emitting element package of the present invention.

FIG. 3 is a view showing one example of a method for manufacturing a substrate for a light emitting element package of the present invention.

### DESCRIPTION OF THE SYMBOLS

1 insulating layer
2 thick metal section
3 surface electrode section
4 light emitting element
7 sealing resin
21 metal layer
22 heat conductive mask section
24 laminate
25 laminate (substrate member)
30a, 30b roll

### BEST MODES FOR CARRYING OUT THE INVENTION

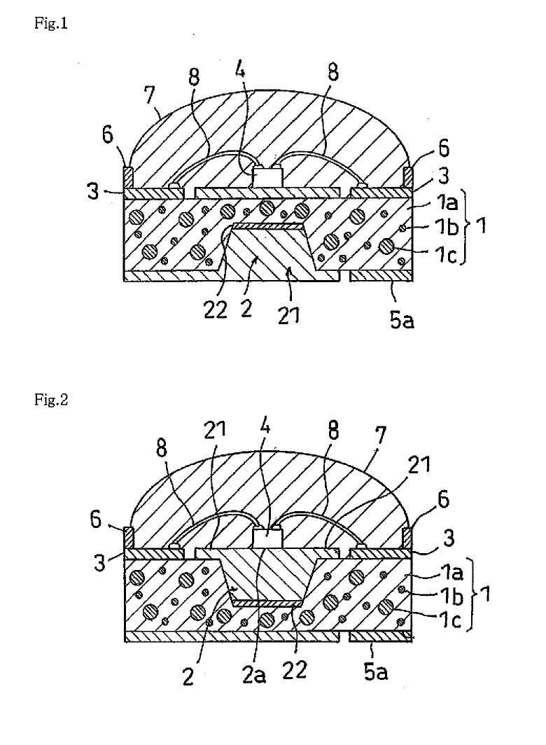

Hereafter, embodiments of the present invention will be described with reference to the drawings. FIGS. 1 and 2 are a cross-sectional view showing one example of a substrate for a light emitting element package of the present invention, showing a state in which a light emitting element is mounted and packaged.

Referring to FIG. 1, the substrate for a light emitting element package according to one example of the present invention includes an insulating layer 1 composed of a resin 1a containing heat conductive fillers 1b, 1c and a metal layer 21 having the thick metal section 2 disposed inside the insulating layer 1, where a heat conductive mask section 22 is provided at the top of the thick metal section 2. Further, a light emitting element 4 is disposed on the mounting side surface of the insulating layer 1, and a surface electrode section 3 is provided on the mounting side surface of the insulating layer 1.

Also, referring to FIG. 2, the substrate for a light emitting element package according to another example of the present invention includes an insulating layer 1 composed of a resin 1a containing heat conductive fillers 1b, 1c, a metal layer 21 having a thick metal section 2 and disposed under a mounting position of the light emitting element 4, where a heat conductive mask section 22 is provided at the top of the thick metal section 2, and a surface electrode section 3 formed on a mounting side surface of the insulating layer 1. Further, the light emitting element 4 is mounted directly on a mounting surface 2a of the metal layer 21. The thick metal section 2 is formed to be thick from the mounting surface 2a towards the back side of the insulating layer 1, and the top side thereof is contained in the inside of the insulating layer 1 (buried state).

In this manner, in the case of a structure in which the top side of the thick metal section 2 does not penetrate through the insulating layer 1, the structure can be produced by pressing with use of a roll or the like described later or by intermittent pressing, thereby enabling mass production, cost reduction, and downsizing.

The insulating layer 1 in the present invention has a heat conductivity of 1.0 W/mK or more, preferably a heat conductivity of 1.2 W/mK or more, more preferably a heat conductivity of 1.5 W/mK or more. By this, the heat from the thick metal section 2 and the heat conductive mask section 22 can be efficiently dissipated to the whole package. Here, the heat conductivity of the insulating layer 1 is determined by suitably selecting a blend in consideration of the amount of blending the heat conductive fillers and the particle size distribution. Typically, however, in consideration of the application property of the insulative adhesive agent (for example, the following thermosetting resin or the like) before curing, the heat conductivity preferably has an upper limit of about 10 W/mK.

The insulating layer 1 is preferably composed of heat conductive fillers 1b, 1c, which are metal oxide and/or metal nitride, and a resin 1a. The metal oxide and metal nitride are preferably excellent in heat conductivity and electrically insulative. As the metal oxide, aluminum oxide, silicon oxide, beryllium oxide, and magnesium oxide can be selected. As the metal nitride, boron nitride, silicon nitride, and aluminum nitride can be selected. These can be used either alone or as a combination of two or more kinds. In particular, among the aforesaid metal oxides, aluminum oxide facilitates obtaining an insulating adhesive agent layer having both a good electric insulation property and a good heat conduction property, and also is available at a low price, so that it is preferable. Also, among the aforesaid metal nitrides, boron nitride is excellent in electric insulation property and heat conductivity, and further has a low electric permittivity, so that it is preferable.

As the heat conductive fillers 1b, 1c, those containing small-diameter fillers 1b and large-diameter fillers 1c are preferable. In this manner, by using two or more kinds of particles having different sizes (particles having different particle size distributions), the heat conductivity of the insulating layer 1 can be further improved by the heat conduction function provided by the large-diameter fillers 1c themselves and the function of enhancing the heat conductivity of the resin between the large-diameter fillers 1c that is provided by the small-diameter fillers 1b. From such a viewpoint, the median diameter of the small-diameter fillers 1b is preferably 0.5 to 2 μm, more preferably 0.5 to 1 μm. Also, the median diameter of the large-diameter fillers 1c is preferably 10 to 40 μm, more preferably 15 to 20 μm.

Also, the thick metal section 2 and the heat conductive mask section 22 extend into the inside of the insulating layer 1, and the heat conductive mask section 22 and the fillers (1b, 1c) of the insulating layer 1 are brought into contact with one another, whereby the heat dissipation property from the light emitting element is improved.

As the resin 1a constituting the insulating layer 1, those having an excellent bonding force to the surface electrode section 3 and the metal pattern 5 under a cured state and not deteriorating the breakdown voltage characteristics and the like though containing the aforesaid metal oxide and/or metal nitride are selected.

As such a resin, in addition to epoxy resin, phenolic resin, and polyimide resin, various engineering plastics can be used either alone or by mixing two or more kinds. Among these, epoxy resin is preferable because of having an excellent bonding force between metals. In particular, among the epoxy resins, a bisphenol-A type epoxy resin, a bisphenol-F type epoxy resin, a hydrogenated bisphenol-A type epoxy resin, a hydrogenated bisphenol-F type epoxy resin, a triblock polymer having a bisphenol-A type epoxy resin structure at both terminal ends, and a triblock polymer having a bisphenol-F type epoxy resin structure at both terminal ends, which have a high fluidity and are excellent in the mixing property with the aforesaid metal oxide and metal nitride, are further more preferable resins.

For the metal layer 21 having the thick metal section 2, the surface electrode section 3, and the metal pattern 5a in the present invention, various metals can be used. Typically, however, any one of copper, aluminum, nickel, iron, tin, silver, and titanium or an alloy or the like containing these metals can be used. In particular, from the viewpoint of heat conduction property and electrical conduction property, copper is preferable.

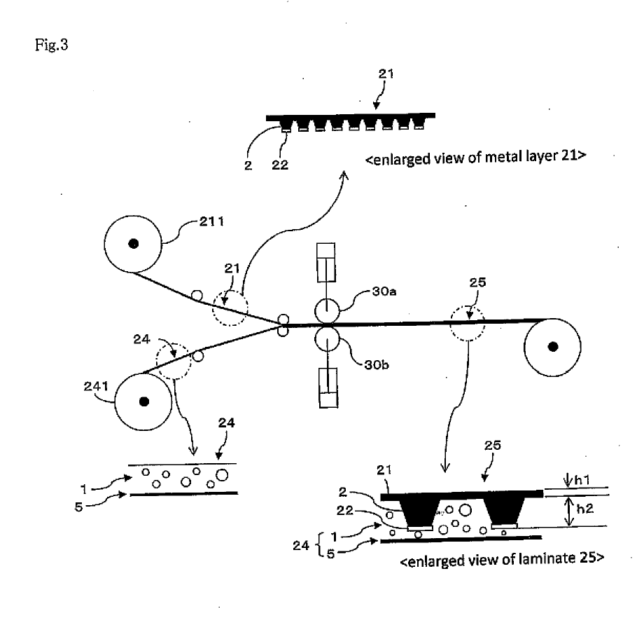

The thick metal section 2 is provided in the metal layer 21. The thickness of the thick metal section 2 is larger than the thickness of the metal layer 21. Also, the thickness of the metal layer 21 (h1: see FIG. 3) and the thickness of the thick metal section 2 and the heat conductive mask section 22 (h2: see FIG. 3) are preferably 31 to 275 μm, more preferably 35 to 275 μm, in view of sufficiently conducting the heat from the light emitting element 4 to the insulating layer 1. Also, from similar reasons, the portion of the thick metal section 2 and the heat conductive mask section 22 that is contained in the insulating layer 1 preferably has a thickness of 30 to 100%, more preferably 50 to 100%, of the thickness of the insulating layer 1.

Also, in view of sufficiently conducting the heat from the light emitting element 4 to the insulating layer 1, the shape of the thick metal section 2 as viewed in a plan view is suitably selected; however, the shape is further preferably a polygonal shape such as a triangle or a quadrangle, a star-like polygonal shape such as a pentagram or a hexagram, or one in which the corners of any of these are rounded with a suitable circular arc, or further can be a shape that gradually changes from the 2a surface of the thick metal section towards the surface electrode section 3. Also, from similar reasons, the maximum width of the thick metal section 2 as viewed in a plan view is preferably 1 to 10 mm, more preferably 1 to 5 mm.

As a method for forming the thick metal section 2 in the metal layer 21, known forming methods can be adopted, so that the thick metal section 2 can be formed, for example, by etching using the photolithography method, pressing, printing, or bonding, or by a known bump-forming method. Also, in the case of forming the thick metal section 2 by etching, a protective metal layer may intervene. As the protective metal layer, for example, gold, silver, zinc, palladium, ruthenium, nickel, rhodium, a lead-tin series solder alloy, a nickel-gold alloy, or the like can be used.

The heat conductive mask section 22 provided at the top of the thick metal section 2 has a heat conductivity of 1.0 W/mK or more, preferably a heat conductivity of 1.2 W/mK or more, and more preferably a heat conductivity of 1.5 W/mK or more. In particular, the heat conductive mask section 22 preferably has a heat conductivity equivalent to or more than that of the insulating layer 1 and has a small heat capacity.

Also, as a method for forming the heat conductive mask section 22 at the top of the thick metal section 2, for example, printing, bonding, and the like are exemplified. Also, in the case of forming the thick metal section 2 by etching using the photolithography method, it is preferable to use the heat conductive mask section as an etching resist, whereby the step of removing this heat conductive mask section can be omitted.

The thickness of the heat conductive mask section 22 is 1 μm or more and, for example, 10 to 100 μm are exemplified. When the thickness is too large, the shape change of the end portion will be large at the time of laminating with the insulating layer 1, so that it is not preferable. When the thickness is too small, the heat conductivity lowers, so that it is not preferable.

As a material for the heat conductive mask section 22, for example, an interlayer insulating material other than the insulating layer 1, an etching resist, a dry film resist, a solder, a solder paste, an electrically conductive adhesive agent, a heat conductive adhesive agent, a resist or a flux for solder, and the like can be exemplified. Among these, an interlayer insulating material other than the insulating layer 1 and an etching resist are suitably used.

The thickness of the surface electrode section 3 is preferably about 25 to 70 for example. Also, the thickness of the metal pattern 5a is preferably about 25 to 70 μm, for example. Here, the metal pattern 5a may cover the whole of the back surface of the insulating layer 1 or may have a thick metal section 2 in the same manner as the metal layer 21. Regarding the metal pattern 5a, in view of evading a short circuit of the surface electrode section 3, it is preferable that at least the metal patterns 5a of the back surfaces of the surface electrode sections 3 on both sides are not electrically conducted. In particular, when the thick metal section 2 is provided also in the metal pattern 5a, attention must be paid so that a positional shift may not be generated in the following lamination and integration step. Also, it is preferable that the metal pattern 5a is formed in advance in a B-stage state of an insulating adhesive agent.

In view of enhancing the reflection efficiency, it is preferable to perform plating with a noble metal such as silver, gold, or nickel on the thick metal section 2, the metal layer 21, and the surface electrode section 3. Also, in the same manner as a conventional interconnect substrate, a solder resist may be formed, or partial solder plating may be performed.

### (Manufacturing Method)

Next, a suitable method for manufacturing a substrate for a light emitting element package of the present invention such as shown above will be described with reference to FIG. 3. Referring to FIG. 3, a metal layer roll body 211 is prepared in which a long metal layer 21, on which a thick metal section 2 having a heat conductive mask section 22 provided at the top thereof is formed, is wound up. The size in the width direction, the arrangement of the thick metal section 2 and the like are appropriately set. The thick metal section 2 is formed by etching using the photolithography method, and the heat conductive mask section 22 is no other than the one used as an etching resist thereof.

Also, an insulating layer roll body 241 is prepared in which a laminate 24 of a long insulating layer 1 in a B stage state and a long metal layer 5 is wound up. The size in the width direction is appropriately set; however, it is preferably of the same degree as the size of the metal layer roll body 211 in the width direction. A release protective layer may be provided on the surface of the long insulating layer 1. In this case, the release protective layer is peeled off at the time of laminating with the metal layer 21.

The roll for lamination is constructed with a pair of rolls (30a, 30b), as shown in FIG. 3. Also, the roll pair (30a, 30b) may be constructed with a plurality of roll pairs. Also, the roll pair (30a, 30b) can be constructed to press the metal layer 21 and the laminate 24 via a plate-shaped body (on one side or on both sides: not illustrated). It is possible to adopt a construction in which the roll pair and the plate-shaped body intervening roll pair are combined. The material of the roll, the size of the roll, and the like are suitably set in accordance with the specification of the laminate 25 (substrate member) in which the metal layer 21 and the laminate 24 are laminated and integrated. As the plate-shaped body, a hard metal plate and a hard resin plate having a good planar property can be exemplified. Also, a belt press can be used as well. Furthermore, a pressing machine of intermittent type can be used as well by drawing the metal layer 21 and the laminate 24 out in a stepping manner.

The distance between the roll pair (30a, 30b) is constructed to be adjustable. This distance is set in accordance with the conditions such as the thickness of the laminate 25 in which the metal layer 21 and the laminate 24 are laminated, the thickness of the portion of the thick metal section 2 that is contained in the inside of the insulating layer 1, and the lamination step operation conditions (transportation speed and the like). The pressing force of the roll pair (30a, 30b) is set in accordance with the specification of each of the metal layer 21, the insulating layer 1 constituting the laminate 24, and the laminate 25 in which these are laminated. Also, the distance between the roll pair (30a, 30b) may be fixed at the time of forming the laminate 25, or may be constructed to be movable in the vertical direction relative to the laminate 25. In the case of constructing to be movable in the vertical direction, known means can be applied and, for example, a spring, a hydraulic cylinder, an elastic member, and the like can be exemplified.

Hereafter, the manufacturing method shown in FIG. 3 will be described. First, the long metal layer 211 is drawn out from the metal layer roll body 22 and is sent out to the roll pair (30a, 30b) side. In synchronization with this, the long laminate 24 is drawn out from the roll body 241 of the laminate 24 of the insulating layer 1 in the B-stage state and the metal layer 5, and is sent out to the roll pair (30a, 30b) side. Subsequently, these are transported to a gap between the roll pair (30a, 30b), where a pressing action is performed on the metal layer 21 and the laminate 24 by the roll pair (30a, 30b), whereby the metal layer 21 and the laminate 24 are laminated and integrated to form the laminate 25. In FIG. 3, the laminate 25 is formed in a state in which the thick metal section 2 is buried in the inside of the insulating layer 1 of the laminate 24. In FIG. 3, the laminate 25 is formed in a state in which the heat conductive mask section 22 and the thick metal section 2 are buried in the inside of the insulating layer 1 of the laminate 24.

Also, it is possible to adopt a construction in which the roll itself is heated and pressing (simultaneous heating pressing) is carried out while allowing the heat to act. It will be effective if the bonding property to the metal layer 21 is improved when the insulating layer 1 is heated. Further, it is possible to adopt a construction in which a heating apparatus is disposed on the upstream side and/or the downstream side of the roll pair (30a, 30b), whereby the bonding of the insulating layer 1 to the metal layer 21 can be efficiently carried out.

Also, it is possible to adopt a construction in which an adhesive agent is applied on the lamination surface side of the metal layer 21 and/or the insulating layer 1, whereby the bonding force can be reinforced.

Also, for the purpose of retaining and stabilizing the thickness, it is possible to adopt a construction in which a plurality of roll pairs (pressing roller pairs) and/or flat plate section pairs are disposed on the downstream side of the roll pair (30a, 30b), whereby the thickness precision of the laminate 25 can be made to be a high precision. Also, for the purpose of cooling, a cooling roller, a cooling apparatus, or the like can be provided on the downstream side of the roll pair (30a, 30b).

The laminate 25 in which the metal layer 21 and the laminate 24 are laminated with use of a roll is introduced to and passed through the inside of a heating apparatus in a suitable condition, so as to cure the insulating layer 1 in a B-stage state into a C-stage state. Subsequently, this is cut into a predetermined size with use of a cutting apparatus such as a dicer, a router, a line cutter, or a slitter. Here, the curing of the laminate 25 can be carried out after the cutting. Also, upon progressing the curing reaction before the cutting, a post-curing treatment can be carried out after the cutting. In this case, an in-line heating apparatus can be provided before the cutting or, alternatively, the curing reaction can be carried out off-line in a heating apparatus after winding and collecting in a roll form.

Subsequently, both surfaces of the laminate 25 are patterned by etching using the photolithography method, so as to form the surface electrode section 3 and the metal pattern 5a, whereby the substrate for a light emitting element package of the present invention can be obtained. Also, for example, it is possible to adopt a construction in which a part of the metal layer 21 is removed so that the remaining part may form the metal pattern 5a, and a part of the metal layer 5 is removed so that the remaining part may form the surface electrode section 3, as shown in FIG. 1. Also, it is possible to adopt a construction in which a part of the metal layer 21 is removed so that the remaining part may form the surface electrode section 3, and a part of the metal layer 5 is removed so that the remaining part may form the metal pattern 5a, as shown in FIG. 2.

At this time, the substrate for a light emitting element package of the present invention may be of a type in which a single light emitting element is mounted as shown in FIG. 1, 2 or of a type in which a plurality of light emitting elements are mounted. In particular, in the latter case, the substrate preferably has a wiring pattern that wires between the surface electrode sections 3.

Also, the substrate for a light emitting element package is used by mounting a light emitting element 4 on the metal layer 21 above the thick metal section 2 of the substrate for the light emitting element package and sealing the light emitting element 4 with a sealing resin 7, for example, as shown in FIG. 2.

In other words, the light emitting element package includes a substrate for a light emitting element package including an insulating layer 1 composed of a resin la containing heat conductive fillers 1b, 1c, a metal layer 21 provided with a thick metal section 2 formed under a mounting position of a light emitting element 4, and a surface electrode section 3 formed on a mounting side surface of the insulating layer 1; a light emitting element 4 mounted above the thick metal section 2; and a sealing resin 7 for sealing the light emitting element 4.

As the light emitting element 4 to be mounted, a LED chip, a semiconductor laser chip, and the like can be exemplified. Besides a face-up type in which both electrodes are present on an upper surface, the LED chip may be of a cathode type, an anode type, a face-down type (flip chip type), or the like depending on the back surface electrode. In the present invention, it is preferable to use a face-up type in view of the heat dissipation property.

The mounting method of the light emitting element 4 on the mounting surface of the metal layer 21 may be any bonding method such as bonding with use of an electrically conductive paste, a two-sided tape, or a solder, or a method using a heat dissipating sheet (preferably a silicone series heat dissipating sheet), a silicone series or epoxy series resin material; however, bonding by metal is preferable in view of heat dissipation.

The light emitting element 4 is electrically conducted and connected to the surface electrode sections 3 on both sides. This electrical conduction and connection can be implemented by wiring between the upper electrode of the light emitting element 4 and each of the surface electrode sections 3 by wire bonding or the like using fine metal lines 8. For wire bonding, supersonic wave, a combination of this with heating, or the like can be used.

With regard to the light emitting element package of the present embodiment, an example is shown in which a dam section 6 at the time of potting a sealing resin 7 is disposed; however, the dam section 6 can be omitted. As a method of forming the dam section 6, a method of bonding an annular member, a method of applying and curing an ultraviolet-curing resin or the like in a three-dimensional manner and in an annular manner with a dispenser, or the like method can be used.

As a resin used for potting, a silicone series resin, an epoxy series resin, and the like can be suitably used. For potting of the sealing resin 7, the upper surface thereof is preferably formed in a convex shape in view of imparting a function of a convex lens; however, the upper surface may be formed in a planar shape or in a concave shape. The upper surface shape of the potted sealing resin 7 can be controlled by the viscosity, the application method, the affinity to the applied surface, and the like of the material to be used.

In the present invention, a transparent resin lens having a convex shape may be provided above the sealing resin 7. When the transparent resin lens has a convex shape, light can be efficiently emitted upwards from the substrate in some cases. As the lens having a convex shape, those having a circular or elliptic shape as viewed in a plan view and the like can be raised as examples. Here, the transparent resin or the transparent resin lens may be a colored one or may be one containing a fluorescent substance. In particular, in the case of containing a yellow series fluorescent substance, white light can be generated by using a blue light emitting diode.

### OTHER EMBODIMENTS

(1) In the above-described embodiments, an example has been shown in which a light emitting element of a face-up type is mounted. However, in the present embodiment, a light emitting element of a face-down type provided with a pair of electrodes on the bottom surface may be mounted. In that case, there are cases in which there will be no need of wire bonding or the like by performing solder bonding or the like. Also, in the event that the front surface and the back surface of the light emitting element has an electrode, the wire bonding or the like can be formed with use of a single line.

(2) In the above-described embodiment, an example has been shown in the case where the light emitting element is mounted on a substrate in which the wiring layer is a single layer. However, in the present invention, the light emitting element may be mounted on a multi-layer wiring substrate in which the wiring layers are provided as plural layers. Details of the method for forming the electrically conductive connection structure in that case are disclosed in International Patent Publication WO00/52977, and any of these can be applied.

(3) Also, as another embodiment, there is a case in which the laminate 24 is not constructed in a roll form. In this case, while drawing out the metal layer 5 provided in a roll form, an insulating adhesive agent is continuously applied on the surface, thereby to construct the laminate 24. On this laminate 24, the metal layer 21 is continuously laminated by using the aforesaid process, so as to obtain the laminate 25. At this time, the insulating adhesive agent of the laminate 24 may be half-cured into a B-stage state before lamination to the metal layer 21.

(4) As another embodiment, the metal layer 21 is obtained by continuously forming a thick metal section using the aforesaid process while drawing out a base metal of the metal layer 21. The laminate 25 is obtained by continuously laminating the laminate 24 on this metal layer 21 using the aforesaid process.

1. A substrate for a light emitting element package provided with a thick metal section formed under a mounting position of a light emitting element, comprising:
an insulating layer which is composed of a resin containing heat conductive fillers under the mounting position of said light emitting element and has a heat conductivity of 1.0 W/mK or more; and
a metal layer disposed inside said insulating layer and having the thick metal section,
wherein a heat conductive mask section is disposed at the top of said thick metal section.

2. The substrate for a light emitting element package according to claim 1, wherein said heat conductive fillers are constructed with two or more kinds of particles having different sizes.

3. The substrate for a light emitting element package according to claim 1, wherein said heat conductive fillers are constructed with small-diameter heat conductive fillers having a median diameter of 0.5 to 2 μm and large-diameter heat conductive fillers having a median diameter of 10 to 40 μm.

4. The substrate for a light emitting element package according to claim 1, wherein said heat conductive mask section has a heat conductivity of 1.0 W/mK or more.

5. The substrate for a light emitting element package according to claim 1, wherein said heat conductive mask section has a heat conductivity equivalent to or more than that of said insulating layer.

6. The substrate for a light emitting element package according to claim 1, wherein said heat conductive mask section is constructed with an etching resist used in forming said thick metal section.

7. A method for manufacturing a substrate for a light emitting element package provided with a thick metal section formed under a mounting position of a light emitting element, having:
a lamination step of laminating and integrating a laminate having an insulating adhesive agent which is composed of a resin containing heat conductive fillers and has a heat conductivity of 1.0 W/mK or more and a metal layer member, with a metal layer member having a thick metal section provided with a heat conductive mask section.

8. A method for manufacturing a substrate for a light emitting element package according to claim 7, wherein said heat conductive fillers are constructed with two or more kinds of particles having different sizes.

9. A method for manufacturing a substrate for a light emitting element package according to claim 7, wherein said heat conductive fillers are constructed with small-diameter heat conductive fillers having a median diameter of 0.5 to 2 μm and large-diameter heat conductive fillers having a median diameter of 10 to 40 μm.

10. A method for manufacturing a substrate for a light emitting element package according to claim 7, wherein said heat conductive mask section has a heat conductivity of 1.0 W/mK or more.

11. A method for manufacturing a substrate for a light emitting element package according to claim 7, wherein said heat conductive mask section has a heat conductivity equivalent to or more than that of said insulating layer.

12. A method for manufacturing a substrate for a light emitting element package according to claim 7, wherein said heat conductive mask section is constructed with an etching resist used in forming said thick metal section.

13. The method for manufacturing a substrate for a light emitting element package according to claim 7, wherein said laminate having the insulating adhesive agent and the metal layer member and/or said metal layer member having the thick metal section provided with the heat conductive mask section are provided in a roll form in advance.

14. A light emitting element package using a substrate for a light emitting element package according to claim 1.

15. A light emitting element package using a substrate for a light emitting element package manufactured according to claim 7.
